(19) United States
(12) Patent Application Publication
(10) Pub. No.: US 2026/0190769 A1
(43) Pub. Date: Jul. 2, 2026

(54) DISPLAY DEVICE

(71) Applicant: LG Display Co., Ltd., Seoul (KR)

(72) Inventor: Hyein PARK, Gwangju (KR)

(73) Assignee: LG Display Co., Ltd., Seoul (KR)

(21) Appl. No.: 19/431,166

(22) Filed: Dec. 23, 2025

(30) Foreign Application Priority Data
Dec. 31, 2024 (KR) 10-2024-0202541

(51) Int. Cl. H10K 59/80; H10K 59/127

(52) U.S. Cl. CPC H10K 59/8722; H10K 59/127; H10K 59/8721; H10K 59/873; H10K 59/874

(57) ABSTRACT

The present disclosure relates to a display device that includes a trench structure formed by removing a part of a planarization layer in a non-display area. The planarization layer includes a first planarization layer disposed in a display area and a second planarization layer disposed in the non-display area, with the trench structure located between them. The second planarization layer further includes a plurality of protrusions on its upper surface. By providing the trench structure and the protrusions, moisture or oxygen introduced from the outside can be more effectively managed, thereby reducing deterioration of the display device and improving reliability.

### CROSS-REFERENCE TO RELATED APPLICATIONS

This application claims the priority of Korean Patent Application No. 10-2024-0202541 filed on Dec. 31, 2024, in the Korean Intellectual Property Office, the disclosure of which is incorporated herein by reference.

### BACKGROUND

### Technical Field

The present disclosure relates to a display device, and more particularly, to a display device which minimizes deterioration of the display device due to moisture and oxygen.

### Description of the Related Art

Recently, as it enters an information era, a display field which visually expresses electrical information signals has been rapidly developed, and in response to this, various display devices having excellent performances such as thin-thickness, light weight, and low power consumption have been developed. Examples of such a display device include a liquid crystal display device (LCD) and an organic light emitting display device (OLED).

The organic light emitting display device is a self-emitting display device and does not require a separate light source unlike a liquid crystal display device, and thus may be manufactured in a lightweight and thin form. In addition, the organic light emitting display device is advantageous not only in terms of power consumption due to low voltage driving, but also in terms of color implementation, response speed, viewing angle, contrast ratio (CR), so it is being studied as a next-generation display.

### BRIEF SUMMARY

The disclosed display device employs a trench that separates the planarization layer into an inner portion located in the display area and an outer portion located in the non-display area. By removing part of the planarization layer in this peripheral region, the structure interrupts the continuous path through which moisture and oxygen would ordinarily travel. The cathode and protective layer extend to cover the side surface of the inner planarization layer, forming a barrier configuration that further restricts the progression of moisture toward the display elements.

The structure also ensures that the outer planarization layer is directly exposed to the adhesive layer that contains a getter, with the adhesive material additionally filling the trench. As a result, moisture entering from the periphery is guided toward the adhesive layer, where it can be absorbed by the getter, rather than migrating inward toward the organic light emitting elements. This arrangement improves the effectiveness of the getter compared to structures in which an inorganic barrier layer blocks access.

The outer planarization layer further includes protrusions that increase the contact area with the adhesive layer and enhance adhesion. Various embodiments also place patterned protective layer portions on top of the protrusions or in regions between them. These structures improve mechanical bonding while maintaining pathways that allow moisture to be collected by the getter, thereby enhancing the overall moisture management performance of the display device.

Accordingly, various embodiments of the present disclosure ensure that moisture or oxygen in a display device is smoothly absorbed by a getter and to maximize a function of a protective layer having an excellent barrier characteristic to suppress moisture permeation and improve the reliability of the display device.

Various embodiments of the present disclosure provide a display device in which an adhesive force between a planarization layer and an adhesive filler is enhanced in an outer portion of a non-display area.

Technical benefits of the present disclosure are not limited to the above-mentioned benefits, and other benefits, which are not mentioned above, can be clearly understood by those skilled in the art from the following descriptions.

According to an aspect of the present disclosure, a display device includes a first substrate including a display area and a non-display area, a planarization layer disposed in the display area and the non-display area on the first substrate, an anode disposed on the planarization layer, an organic layer disposed on the anode, a cathode disposed on the organic layer, a protective layer disposed on the cathode, a second substrate disposed on the protective layer so as to face the first substrate, and an adhesive layer disposed on the protective layer and the second substrate and bonding the first substrate and the second substrate, in the non-display area, the display device includes a trench structure from which a part of the planarization layer is removed, and the planarization layer includes a first planarization layer disposed in the display area and a second planarization layer disposed in the non-display area, the trench structure is disposed between the first planarization layer and the second planarization layer, and the second planarization layer includes a plurality of protrusions on the upper surface of the second planarization layer.

Other detailed matters of the embodiments are included in the detailed description and the drawings.

In the display device according to the present disclosure, a trench structure is formed in the planarization layer in the non-display area, and the protection layer is disposed so as to cover the side surface of the planarization layer disposed on the display area with respect to the trench structure, so that moisture or oxygen may be easily absorbed by the getter.

According to the present disclosure, a display device includes a plurality of protrusions on a planarization layer disposed on a non-display area with respect to a trench structure, which allows moisture or oxygen introduced into the planarization layer to be easily absorbed by a getter dispersed in the adhesive layer while maintaining a high adhesive force with the adhesive layer.

Accordingly, the display device according to the present disclosure has the advantage of excellent moisture permeability reliability by suppressing the propagation of moisture or oxygen toward the display area.

The effects according to the present disclosure are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a cross-sectional view of a conventional display device.

FIG. 2 is a plan view of a display device according to an embodiment of the present disclosure.

FIG. 3 is a cross-sectional view of one sub-pixel in the display device according to the embodiment of the present disclosure.

FIG. 4 is a cross-sectional view taken along the line I-I′ of FIG. 2.

FIG. 5 is a cross-sectional view of a display device according to another embodiment of the present disclosure.

FIG. 6 is a cross-sectional view of a display device according to still another embodiment of the present disclosure.

FIG. 7 is a cross-sectional view of a display device according to still another embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The terms “coupled” and “in contact” should be interpreted in the same manner.

The phrase “A filled in B” does not imply that A is exclusively contained within B to the exclusion of other materials. Instead, it is intended to encompass a broad range of conditions, including but not limited to “partially filled in,” “substantially filled in,” “completely filled in,” and “exclusively filled in.” Similarly, the phrase “B filled with A” does not suggest that B is exclusively filled with A, excluding other materials. Rather, it covers various degrees of filling, such as “partially filled with,” “substantially filled with,” “completely filled with,” and “exclusively filled with.”

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

Firstly, the light emitting element of the organic light emitting display device is formed using an organic material and is vulnerable to oxygen or moisture. For this reason, the organic light emitting device is easily deteriorated by internal factors such as deterioration of the electrode and the light emitting layer due to oxygen and deterioration due to the reaction at the interface adjacent to the light emitting layer, and also by external factors such as moisture, oxygen, ultraviolet rays, and device manufacturing conditions. In particular, since external oxygen and moisture have a fatal effect on the life of the device, the encapsulation technology of the organic light emitting display device is very important.

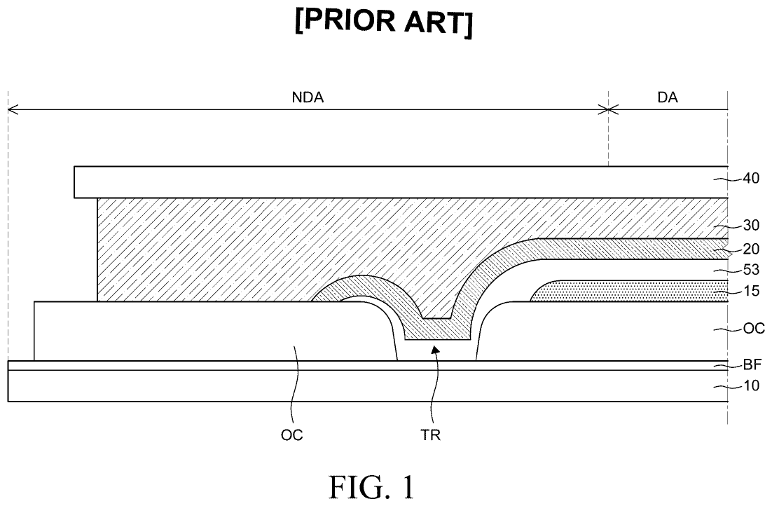

FIG. 1 is a cross-sectional view of a conventional display device.

Referring to FIG. 1, in the display device, in order to seal the organic light emitting element 15, a buffer layer BF, a planarization layer OC, organic light emitting elements 15 and 53 and a protection layer 20 are formed on a lower substrate 10 which is an array substrate, and an adhesive filler 30 including a getter is used to bond and seal the upper substrate 40 which is an encapsulation substrate. At this time, in order to prevent moisture permeation and ensure reliability, a trench TR is formed in the planarization layer OC vulnerable to moisture permeation in the non-display area. Accordingly, the planarization layer OC formed of the organic material has a structure separated by the trench TR. Further, the area exposed by the trench TR is covered by the cathode 53 extending from the display area DA and the protective layer 20 to delay the progress of moisture or oxygen to the display area DA.

However, in this case, it may be limited in maximizing the moisture trapping ability of the getter dispersed in the adhesive filler 30 by the protective layer 20 having relatively high barrier properties. In addition, since moisture introduced through the planarization layer OC is blocked by the protective layer 20, there is a problem in that moisture cannot be absorbed by the getter and stays in the planarization layer OC, and eventually moisture penetration into the display area is accelerated.

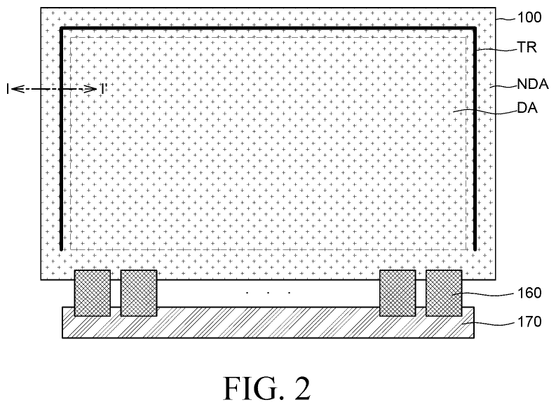

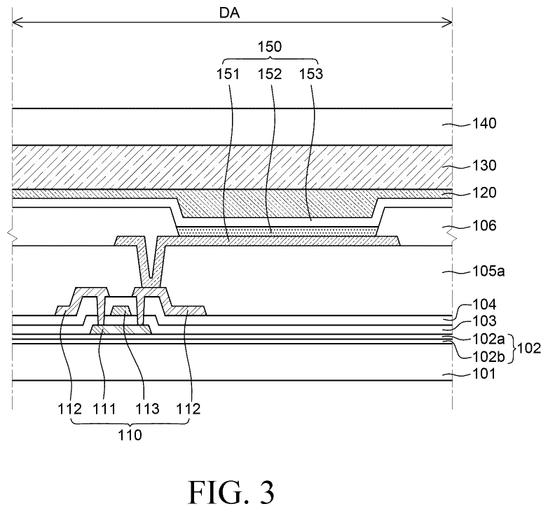

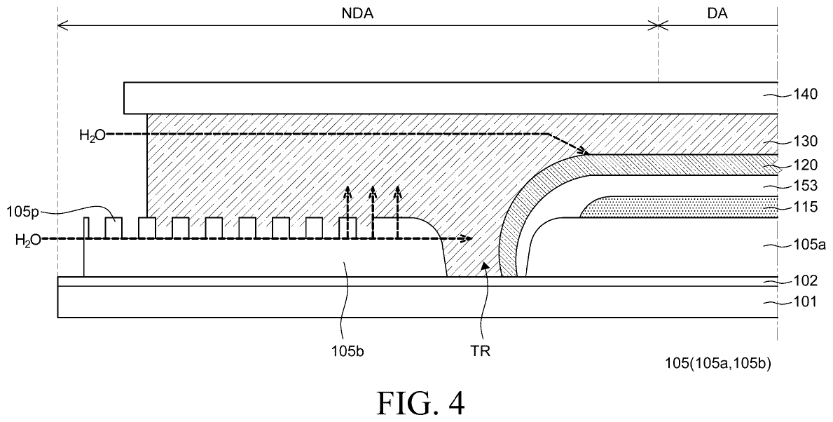

FIG. 2 is a plan view of a display device according to an exemplary embodiment of the present disclosure, FIG. 3 is a cross-sectional view of one sub-pixel in the display device according to an exemplary embodiment of the present disclosure, and FIG. 4 is a cross-sectional view taken along line I-I′ of FIG. 2.

Referring to FIGS. 2 to 4, a display device according to an exemplary embodiment of the present disclosure includes a display panel 100, a flexible film 160, and a printed circuit board 170. Specifically, the display panel 100 includes a first substrate 101, a thin film transistor 110, a planarization layer 105, an anode 151, an organic layer 152, a cathode 153, a protective layer 120, an adhesive layer 130, and a second substrate 140.

The display panel 100 is a panel for displaying an image to a user. The display panel 100 may include a display element for displaying images, a driving element for driving the display element, and line for transmitting various signals to the display element and the driving element. The display element may be different according to the type of the display panel 100. For example, the display panel 100 may be an organic light emitting display panel, and in this case, the display element may be an organic light emitting element 150 including an anode 151, an organic layer 152, and a cathode 153.

The display panel 100 may include a display area DA and a non-display area NDA.

In the display area DA, a plurality of sub-pixels constituting a plurality of pixels and a circuit for driving the plurality of sub-pixels may be disposed. The plurality of sub-pixels is minimum units constituting the display area DA, and a display element may be disposed in each of the plurality of sub-pixels. For example, an organic light emitting element 150 including an anode 151, an organic layer 152, and a cathode 153 may be disposed in each of the plurality of sub-pixels, but it is not limited thereto.

The non-display area NDA is an area where an image is not displayed. FIG. 2 illustrates that the non-display area NDA surrounds the display area DA having a rectangular shape. However, the shapes and arrangements of the display area DA and the non-display area NDA are not limited to the example illustrated in FIG. 2. A circuit for driving the plurality of sub-pixels may include a driving element, a line, and the like. For example, the circuit may be formed of a thin film transistor, a storage capacitor, a gate line, a data line, or the like, but is not limited thereto.

In the non-display area NDA, various lines and circuits for driving the organic light emitting element 150 of the display area DA may be disposed. For example, in the non-display area NDA, a link line for transmitting signals to the plurality of sub-pixels and circuits of the display area DA or a driving IC such as a gate driver IC and a data driver IC may be disposed, but it is not limited thereto.

The flexible film 160 is a film in which various components are disposed on a flexible base film. Specifically, the flexible film 160 is a film for supplying signals to the plurality of sub-pixels and circuits of the display area DA and may be electrically connected to the display panel 100. The flexible film 160 is disposed at one end of the non-display area NDA of the display panel 100 to supply a power voltage and a data voltage to the plurality of sub pixels and circuits of the display area DA. The number and structure of the flexible films 160 may be variously changed according to design, but are not limited thereto.

For example, a driving IC such as a gate driver IC and a data driver IC may be disposed on the flexible film 160. The driving IC is a component that processes data for displaying an image and a driving signal for processing the data. The driving IC may be disposed by a chip on glass (COG), a chip on film (COF), a tape carrier package (TCP) method, or the like depending on a mounting method.

The printed circuit board 170 may be disposed at one end of the flexible film 160 to be connected to the flexible film 160. The printed circuit board 170 is a component that supplies signals to the driving IC. The printed circuit board 170 may supply various signals, such as a driving signal or a data signal, to the driving IC. For example, a data driver for generating data signals may be mounted on the printed circuit board 170, and the generated data signal may be supplied to the plurality of sub-pixels and circuits of the display panel 100 through the flexible film 160. The number or structure of the printed circuit board 170 may be variously changed according to design, but is not limited thereto.

Hereinafter, the configuration of the display panel 100 will be described in detail with reference to FIGS. 2 and 3.

The first substrate 101 is a substrate for supporting various elements constituting the display panel 100. The first substrate 101 may be a glass or plastic substrate. When the first substrate 101 is a plastic substrate, the first substrate 101 may be selected from polyimide, polyethersulfone, polyethylene terephthalate and polycarbonate, but is not limited thereto. When such a plastic substrate is used as the first substrate 101, it may have flexibility, and in particular, polyimide is a material having high heat resistance and may be easily applied to a high-temperature process.

A buffer layer 102 may be disposed on the first substrate 101. The buffer layer 102 may protect the electrodes and lines from impurities such as hydrogen and alkali ions leaked from the first substrate 101 during a high-temperature process. In addition, the buffer layer 102 may delay the diffusion of moisture or oxygen existing on the first substrate 101 or introduced from the outside to the thin film transistor 110.

The buffer layer 102 may have a single-layered structure or a multi-layered structure. For example, the buffer layer 102 may have a multilayer structure including a first buffer layer 102a and a second buffer layer 102b, but is not limited thereto. For example, the buffer layer 102 may be formed of an inorganic material selected from silicon oxide (SiOx), silicon nitride (SiNx), amorphous silicon (a-Si), and the like, but not limited thereto.

The thin film transistor 110 may be a driving element for driving the organic light emitting element 150 which is a display element. The thin film transistor 110 may include an active layer 111, a gate electrode 113, a source electrode, and a drain electrode 112. In the drawing, among various thin film transistors that may be included in the display device, only a driving thin film transistor is illustrated for convenience, but it is not limited thereto.

The active layer 111 is disposed on the buffer layer 102. For example, the active layer 111 may be formed of a silicon-based material such as polysilicon (p-Si) or amorphous silicon (a-Si) or a semiconductor oxide such as a metal oxide such as In, Ga, and Zn. When the active layer 111 is formed of polysilicon (p-Si), a partial area in contact with the source electrode and the drain electrode 112 may be doped with impurities.

The interlayer insulating layer 103 is disposed on the active layer 111. The interlayer insulating layer 103 may be formed of an inorganic insulating material such as silicon oxide (SiOx) or silicon nitride (SiNx) or an organic insulating material.

The gate electrode 113 may be located on the interlayer insulating layer 103. The gate electrode 113 may be made of various conductive materials, for example, magnesium (Mg), aluminum (Al), nickel (Ni), chromium (Cr), molybdenum (Mo), tungsten (W), gold (Au), copper (CU), titanium (Ti), manganese (Mn), tantalum (Ta), or an alloy thereof.

A gate insulating layer 104 for insulating the gate electrode 113 and the source electrode and the drain electrode 112 may be disposed on the gate electrode 113. The gate insulating layer 104 may be formed of an inorganic insulating material such as silicon oxide (SiOx) or silicon nitride (SiNx) or an organic insulating material.

The source electrode and the drain electrode 112 are disposed on the gate insulating layer 104. The source electrode and the drain electrode 112 may be disposed to be in contact with the active layer 111 exposed through a contact hole formed in each of the interlayer insulating layer 103 and the gate insulating layer 104. For example, the source electrode and the drain electrode 112 may be formed of magnesium (Mg), aluminum (Al), nickel (Ni), chromium (Cr), molybdenum (Mo), tungsten (W), gold (Au), copper (CU), titanium (Ti), manganese (Mn), tantalum (Ta), or an alloy thereof.

Although not illustrated in the drawings, a TFT protective layer for protecting the thin film transistor may be disposed on the source electrode and the drain electrode 112.

A planarization layer 105 is disposed on the thin film transistor 110. It is disposed on the upper surface of the thin film transistor 110 to provide a flat surface. The planarization layer 105 may include a contact hole for electrically connecting one of the source electrode and the drain electrode 112 of the thin film transistor 110 and the anode 151 of the organic light emitting element 150.

For example, the planarization layer 105 may be formed of an organic insulating material such as photo acryl.

The planarization layer 105 may extend from the display area DA to the non-display area NDA and may be substantially disposed on the front surface of the first substrate 101.

Referring to FIGS. 2 to 4 together, the planarization layer 105 includes a trench structure TR in the non-display area NDA. The trench structure TR may be formed by removing a part of the planarization layer 105 disposed outside the display area DA by, for example, laser melting or the like. Accordingly, the planarization layer 105 may be divided into a first planarization layer 105a disposed in the display area DA and a second planarization layer 105b disposed in the non-display area NDA with the trench structure TR interposed therebetween. When the trench structure TR is formed in the planarization layer 105 in the non-display area NDA as described above, the planarization layer 105 which is vulnerable to moisture or oxygen is disconnected to delay the penetration of moisture or oxygen introduced from the outside into the display area DA.

As shown in FIG. 2, the trench structure TR may be formed over three side areas of the non-display area NDA, except for the area to which the flexible film 160 is connected, but is not limited thereto. In some areas of the display panel 100 to which the flexible film 160 is connected, the driving IC arrangement and voltage-applied lines are complicatedly disposed, and the trench structure TR may not be formed because damage by laser may occur during the process of forming the trench structure TR. However, the present disclosure is not limited thereto.

The organic light emitting element 150 is disposed on the planarization layer 105. The organic light emitting element 150 may be disposed to be included in each of the plurality of sub-pixels. The organic light emitting element 150 includes an anode 151, an organic layer 152, and a cathode 153.

The anode 151 is disposed on the planarization layer 105. The anode 151 may be disposed on the first planarization layer 105a so as to correspond to each of the plurality of sub-pixels included in the display area DA.

The anode 151 is a component for supplying holes to the emission layer of the organic layer 152 and may be formed of a conductive material having a high work function. For example, the anode 151 may be a transparent conductive layer formed of transparent conductive oxide (TCO). For example, the anode 151 may be formed of one or more selected from transparent conductive oxides such as indium-tin-oxide (ITO), indium-zinc-oxide (IZO), indium-tin-zinc oxide (ITZO), tin oxide (SnO2), zinc oxide (ZnO), indium-copper-oxide (ICO), and aluminum-doped zinc oxide (Al-doped ZnO, AZO), but is not limited thereto.

When the display device is driven as a top emission type, the anode 151 may further include a reflective layer under the anode 151 to allow light emitted from the light emitting layer to be directed toward the cathode 153 which is an upper direction.

The bank 106 may be disposed on the planarization layer 105. The bank 106 is disposed on the first planarization layer 105a so as to expose at least a portion of the anode 151. That is, the bank 106 may be disposed on the first planarization layer 105a so as to cover an edge of the anode 151. The bank 106 may define an emission area of the organic light emitting element 150 and divide a plurality of adjacent sub-pixels. The bank 106 may be formed of an insulating material to insulate anodes 151 of adjacent sub-pixels from each other. Further, the bank 106 may be formed of a black resin having a high light absorption rate or may include a black dye to suppress color mixture between adjacent sub pixels. For example, the bank 106 may be formed of polyimide resin, acrylic resin, or benzocyclobutene resin, but is not limited thereto.

The organic layer 152 may be disposed on the anode 151 which is not covered by the bank 106 and is exposed. The organic layer 152 includes an emission layer in which electrons and holes are coupled to emit light. The emission layer may be disposed to correspond to the emission area of each of the plurality of sub pixels, and may be formed as a common layer without being separated for each of the plurality of sub pixels.

In order to improve the luminous efficiency of the organic light emitting element 150, the organic layer 152 may further include a hole injection layer, a hole transport layer, an electron transport layer, an electron injection layer, and the like. For example, a hole injection layer and a hole transport layer may be disposed between the anode 151 and the light emitting layer, and an electron transport layer and an electron injection layer may be disposed between the light emitting layer and the cathode 153. In addition, in order to further improve the recombination efficiency of holes and electrons in the emission layer, a hole blocking layer or an electron blocking layer may be further included.

The cathode 153 is disposed on the organic layer 152. The cathode 153 may be formed of a metal material having a low work function to smoothly supply electrons to the emission layer of the organic layer 152. In the case of the top emission type, the cathode 153 may be formed of one or more selected from indium-tin-oxide (ITO), indium-zinc-oxide (IZO), indium-tin-zinc oxide (ITZO), tin oxide (SnO2), zinc oxide (ZnO), indium-copper-oxide (ICO), and aluminum-doped zinc oxide (Al-doped ZnO, AZO), but is not limited thereto. In the case of the bottom emission type, the cathode 153 may be formed of a metal material selected from gold (Au), molybdenum (Mo), magnesium (Mg), palladium (Pd), barium (Ba), aluminum (Al), silver (Ag), copper (Cu), and an alloy including one or more of them, but is not limited thereto. If necessary, a layer formed of a transparent conductive oxide and a layer formed of the above-described metal material may be laminated.

The cathode 153 may extend to the non-display area NDA. In the non-display area NDA, the cathode 153 may be disposed to cover a side surface of the first planarization layer 105a. This will be described later in detail.

The protective layer 120 is disposed on the organic light emitting element 150. The protective layer 120 planarizes the upper surface of the organic light emitting element 150 and protects the organic light emitting element 150 from an external environment. The protective layer 120 may include an inorganic insulating material and/or an organic insulating material. The protective layer 120 may be formed as a single layer or multiple layers.

The protective layer 120 may extend to the non-display area NDA. The protective layer 120 may be disposed to cover a side surface of the first planarization layer 105a in the non-display area NDA. This will be described later in detail.

The adhesive layer 130 and the second substrate 140 are disposed on the protective layer 120.

The second substrate 140 is disposed to face the first substrate 101 with the adhesive layer 130 interposed therebetween. The second substrate 140 protects the organic light emitting element 150 from external moisture, oxygen, and impact. For example, the second substrate 140 may be made of one or more metals selected from aluminum (Al), copper (Cu), tin (Sn), silver (Ag), iron (Fe), and zinc (Zn). These metal materials have high thermal conductivity and high strength. Accordingly, the organic light emitting element 150 may be protected from an external impact. In addition, it is possible to suppress the deterioration of the organic light emitting element 150 by preventing the penetration of moisture or oxygen.

The second substrate 140 is bonded to the first substrate 101 by the adhesive layer 130. The adhesive layer 130 may bond the first substrate 101 and the second substrate 140, and may function as a buffer to protect the organic light emitting element 150 together with the second substrate 140.

The adhesive layer 130 may be formed of a thermosetting resin or a photocurable resin having excellent adhesion. For example, the adhesive layer 130 may be formed of an adhesive material selected from an epoxy-based resin, an acrylic resin, an imide-based resin, a silicone-based resin, and the like, but not limited thereto.

The adhesive layer 130 may include a getter capable of absorbing moisture or oxygen penetrating from the outside. For example, getters include phosphoryl chloride (POCl₃), phosphorus pentoxide (P₂O₅), barium oxide (BaO), magnesium oxide (MgO), calcium oxide (CaO), strontium oxide (SrO), silica (SiO₂), aluminum oxide (Al₂O₃), calcium chloride (CaCl₂), potassium carbonate (K₂CO₃), potassium hydroxide (KOH), sodium hydroxide (NaOH), sodium hydroxide (NaOH), and strontium oxide (SrO). It may be selected from lithium hydroxide (LiOH), lithium sulfate (Li₂SO₄), sodium sulfate (Na₂SO₄), calcium sulfate (CaSO₄), magnesium sulfate (MgSO₄), cobalt sulfate (CoSO₄), gallium sulfate (Ga₂(SO₄)₃), titanium sulfate (Ti(SO₄)₂), nickel sulfate (NiSO₄), and zeolite, but is not limited thereto.

The adhesive layer 130 may extend from the display area DA to the non-display area NDA. That is, the adhesive layer 130 is substantially formed on the entire surface of the display panel 100. The adhesive layer 130 extends to the non-display area NDA and is disposed to cover at least a part of the second planarization layer 105b positioned in the non-display area NDA.

Hereinafter, an arrangement structure of each layer in the non-display area NDA will be described in detail with reference to FIG. 4. In FIG. 4, for the convenience of description, various components disposed below the cathode 153 in the display area DA are schematically illustrated as a pixel unit 115.

As described above, the planarization layer 105 includes a first planarization layer 105a and a second planarization layer 105b disposed with the trench structure TR interposed therebetween. A part of the planarization layer 105 is cut by the trench structure TR to delay a rate at which moisture or oxygen permeating through the second planarization layer 105b located at the outside penetrates toward the display area DA.

The cathode 153 may extend to the non-display area NDA and may be disposed to cover the side surface of the first planarization layer 105a exposed by the trench structure TR. Accordingly, the end of the cathode 153 may be located inside the trench structure TR. In this case, the rate at which moisture or oxygen permeating through the second planarization layer 105b penetrates toward the display area DA may be further delayed.

The protective layer 120 disposed on the cathode 153 may be disposed in a structure similar to that of the cathode 153. The protective layer 120 extends to overlap a portion of the non-display area NDA. The protective layer 120 is disposed on the cathode 153 to cover the side surface of the first planarization layer 105a exposed by the trench structure TR. Accordingly, the end of the protective layer 120 is located inside the trench structure TR. In this case, like the cathode 153, the permeation of moisture or oxygen permeating through the second planarization layer 105b toward the display area DA may be further delayed.

The end of the organic layer 152 is disposed to be located further inward than the end of the first planarization layer 105a. That is, the end of the organic layer 152 is disposed on the upper surface of the first planarization layer 105a. Each of the cathode 153 and the protective layer 120 covers the side surface of the organic layer 152 positioned on the upper surface of the first planarization layer 105a. For example, the end of the organic layer 152 is disposed to be located inside more than each of the end of the cathode 153 and the end of the organic layer 152. Herein, “inside” may refer to a side on which the display area DA is located. Accordingly, the organic layer 152 may be protected from moisture or oxygen penetrating from the outside.

As the cathode 153 and the protective layer 120 are disposed to cover the side surface of the first planarization layer 105a, the cathode 153 and the protective layer 120 are not disposed on the second planarization layer 105b positioned outside the trench structure TR. Accordingly, the upper surface of the second planarization layer 105b is in direct contact with the adhesive layer 130. Accordingly, moisture or oxygen permeating into the second planarization layer 105b may be absorbed by the getter dispersed in the adhesive layer 130. Accordingly, the rate at which moisture or oxygen penetrates into the display area DA may be further delayed, and the reliability of the display device may be greatly improved.

The adhesive layer 130 is filled in the trench structure TR. Accordingly, moisture or oxygen permeating into the second planarization layer 105b may be absorbed by the getter dispersed in the adhesive layer 130 filling the trench structure TR. Accordingly, the rate at which moisture or oxygen penetrates into the display area DA may be further delayed.

A plurality of protrusions 105p are provided on the upper surface of the second planarization layer 105b. The plurality of protrusions 105p may increase the surface area of the second planarization layer 105b to improve the adhesion between the second planarization layer 105b and the adhesive layer 130. When the adhesion is improved in this way, penetration of moisture or oxygen may be suppressed, thereby contributing to the improvement of reliability.

The plurality of protrusions 105p may be formed in various shapes. For example, the plurality of protrusions 105p may each independently be any one shape selected from a bar shape, a circle shape, an elliptical shape, or a polygonal shape. Each of the plurality of protrusions 105p having this shape may be arranged in a matrix or island shape.

Specifically, for example, the plurality of protrusions 105p includes a bar shape extending in a first direction of the display device and a bar shape extending in a second direction different from the first direction, and the bar shape pattern may be arranged in a matrix structure. In this case, the first direction may be a Y-axis direction, and the second direction may be an X-axis direction perpendicular to the first direction. However, the present disclosure is not limited thereto, and the bar-shaped pattern may extend in a diagonal direction between the Y-axis direction and the X-axis direction.

As another example, the plurality of protrusions 105p may have a structure in which patterns having a circle shape, an elliptical shape, or a polygonal shape are arranged in an island shape.

In the display device according to the exemplary embodiment of the present disclosure, a trench structure TR is formed in the planarization layer 105 in the non-display area NDA, and the cathode 153 and the protective layer 120 are disposed so as to cover the side surface of the first planarization layer 105a exposed by the trench structure TR, respectively. Accordingly, the adhesive layer 130 is disposed to fill the inside of the trench structure TR and directly contact the second planarization layer 105b located outside the trench structure TR. Accordingly, when moisture or oxygen penetrates from the outside, the getter dispersed in the adhesive layer 130 may easily absorb oxygen and moisture. Further, the planarization layer 105 has a characteristic relatively vulnerable to moisture or oxygen. Since the second planarization layer 105b in the non-display area NDA is in contact with the adhesive layer 130 over a large area, the planarization layer 105 has an advantage in that it is easy to absorb moisture or oxygen. Further, a plurality of protrusions 105p are provided on the second planarization layer 105b to provide excellent interfacial adhesion between the second planarization layer 105b and the adhesive layer 130 and suppress the penetration of moisture or oxygen. Accordingly, the speed at which moisture or oxygen penetrates into the display area DA is greatly delayed, thereby providing an effect of improving reliability.

Furthermore, when moisture or oxygen penetrates into the display area DA, the organic light emitting element 150 deteriorates, causing a dark spot defect, and according to the present disclosure, the dark spot defect may be improved by delaying the penetration of moisture or oxygen. In addition, even if the bezel area is reduced by significantly delaying the penetration of moisture or oxygen, reliability equal to or higher than that of the conventional display device may be secured.

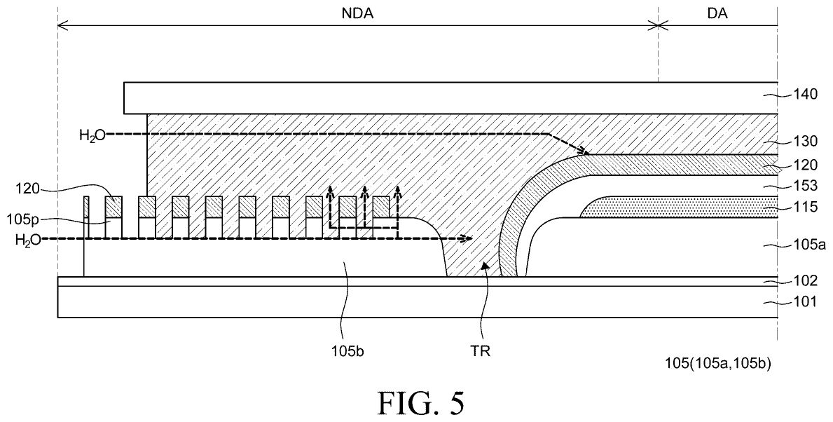

FIG. 5 is a cross-sectional view of a display device according to another embodiment of the present disclosure. The display device illustrated in FIG. 5 is substantially the same as the display device illustrated in FIGS. 2 to 4 except that a protective layer is further disposed on a plurality of protrusions. Therefore, a description of a redundant configuration will be omitted.

According to the present embodiment, the protective layer 120 may also be disposed on the plurality of protrusions 105p formed on the upper surface of the second planarization layer 105b. The protective layer 120 may be patterned to be disposed at a position corresponding to the plurality of protrusions 105p.

For example, each of the plurality of protrusions 105p may be in the form of a bar extending in the first direction of the display device, and the protective layer 120 disposed on the upper surface of each of the plurality of protrusions 105p may be formed in the form of a bar extending in the first direction, similar to the protrusion 105p.

The protective layer 120 has a relatively superior adhesive force with the adhesive layer 130 than the planarization layer 105. Accordingly, when the protective layer 120 is patterned on the plurality of protrusions 105p, adhesion to the adhesive layer 130 may be further improved. In addition, the protective layer 120 is further disposed on the plurality of protrusions 105p, thereby further increasing a surface area in contact with the adhesive layer 130. Accordingly, the adhesive force with the adhesive layer 130 is improved, and the ability to collect oxygen or moisture of the getter dispersed in the adhesive layer 130 may also be further improved.

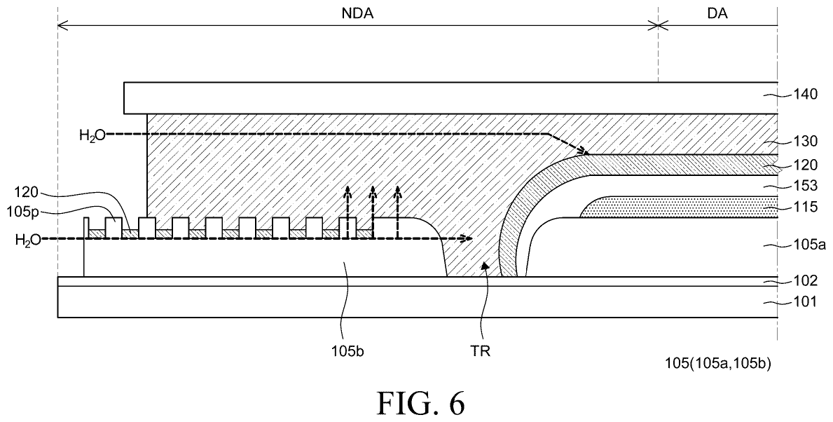

FIG. 6 is a cross-sectional view of a display device according to still another embodiment of the present disclosure. The display device illustrated in FIG. 6 is substantially the same as the display device illustrated in FIGS. 2 to 4 except that a protective layer is further disposed between a plurality of protrusions. Therefore, a description of a redundant configuration will be omitted.

According to the present embodiment, the protective layer 120 may also be disposed between the plurality of protrusions 105p formed on the upper surface of the second planarization layer 105b. That is, the protective layer 120 may be patterned to fill at least a part of the empty space between the plurality of protrusions 105p. Accordingly, the plurality of protrusions 105p and the protective layer 120 are alternately disposed on the upper surface of the second planarization layer 105b.

Specifically, the protective layer 120 may be disposed to fill a part of the empty space between the plurality of protrusions 105p. In this case, a thickness of the protective layer 120 filled between the plurality of protrusions 105p may be smaller than a thickness of the plurality of protrusions 105p. As described above, the protective layer 120 has relatively better adhesion to the adhesive layer 130 than the planarization layer 105. Further, the surface area in contact with the adhesive layer 130 is improved due to the irregularity structure caused by the protective layer 120 filling a part between the plurality of protrusions 105p and the plurality of protrusions 105p. Accordingly, when the protective layer 120 is further disposed between the plurality of protrusions 105p, the adhesive strength between the second planarization layer 105b and the adhesive layer 130 may be further improved. Further, the surface area of the second planarization layer 105b in contact with the adhesive layer 130 is large so that moisture or oxygen penetrating into the second planarization layer 105b may be easily collected by the getter dispersed in the adhesive layer 130.

Accordingly, it is possible to suppress the permeation of moisture or oxygen introduced from the outside toward the display area DA, thereby improving the reliability of the display device.

FIG. 6 illustrates that the protective layer 120 is disposed to fill a part of an empty space between the plurality of protrusions 105p. However, the present disclosure is not limited thereto. The protective layer 120 may be disposed to completely fill an empty space between the plurality of protrusions 105p. That is, the thickness of the protective layer 120 filled between the plurality of protrusions 105p may be the same as the thickness of the plurality of protrusions 105p. In this case, the surface area in contact with the adhesive layer 130 does not increase, but the adhesive force may be increased due to the protective layer 120 having an excellent adhesive force compared to the second planarization layer 105b.

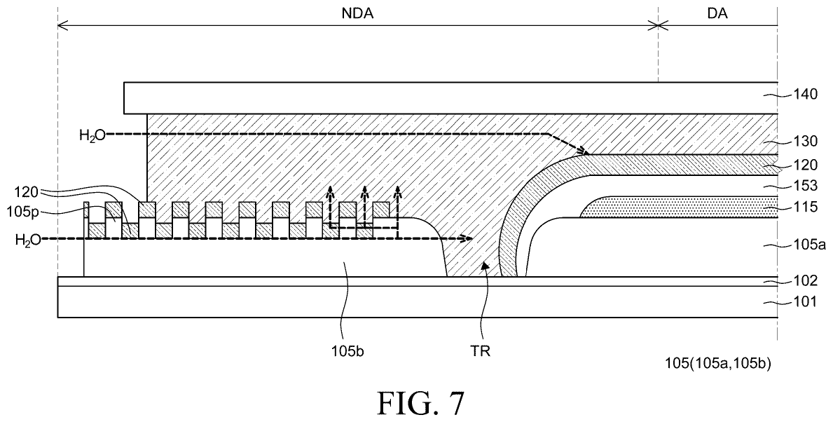

FIG. 7 is a cross-sectional view of a display device according to still another embodiment of the present disclosure. The display device illustrated in FIG. 7 is substantially the same as the display device illustrated in FIGS. 2 to 6 except for the arrangement structure of the protective layer disposed on the second planarization layer. Therefore, a description of a redundant configuration will be omitted.

According to the present embodiment, the protection layer 120 may be disposed on each of the plurality of protrusions 105p formed on the upper surface of the second planarization layer 105b and the empty space between the plurality of protrusions 105p.

Each of the plurality of protrusions 105p may be in the form of a bar extending in the first direction of the display device, and the protective layer 120 disposed on the second planarization layer 105b may be formed in the form of a bar extending in the second direction perpendicular to the first direction. Accordingly, as shown in FIG. 7, the protective layer 120 is disposed on an upper surface of each of the plurality of protrusions 105p and in an empty space between the plurality of protrusions 105p.

The protective layer 120 disposed between the plurality of protrusions 105p may be formed to fill a part of an empty space between the plurality of protrusions 105p. However, it is not limited thereto and may be disposed to fill the entire empty space between the plurality of protrusions 105p.

As described above, the protective layer 120 has relatively better adhesion to the adhesive layer 130 than the planarization layer 105. Accordingly, when the protective layer 120 is disposed in each of the empty spaces between the upper surfaces of the plurality of protrusions 105p and the plurality of protrusions 105p, the adhesive force with the adhesive layer 130 may be further improved. In addition, the surface area in contact with the adhesive layer 130 is increased by the protective layer 120 disposed on the plurality of protrusions 105p, which may improve the adhesion to the adhesive layer 130 and further improve the oxygen or moisture collecting ability of the getter dispersed in the adhesive layer 130.

The exemplary embodiments of the present disclosure can also be described as follows:

According to an aspect of the present disclosure, a display device includes a first substrate including a display area and a non-display area, a planarization layer disposed in the display area and the non-display area on the first substrate, an anode disposed on the planarization layer, an organic layer disposed on the anode, a cathode disposed on the organic layer, a protective layer disposed on the cathode, a second substrate disposed on the protective layer so as to face the first substrate, and an adhesive layer disposed on the protective layer and the second substrate and configured to bond the first substrate and the second substrate, in the non-display area, the display device includes a trench structure from which a part of the planarization layer is removed, the planarization layer includes a first planarization layer disposed in the display area and a second planarization layer disposed in the non-display area, the trench structure is disposed between the first planarization layer and the second planarization layer, and the second planarization layer includes a plurality of protrusions on the upper surface of the second planarization layer.

According to another feature of the present disclosure, the protective layer may be disposed to cover a side surface of the first planarization layer exposed by the trench structure.

According to another feature of the present disclosure, the upper surface of the second planarization layer may be disposed to directly contact the adhesive layer.

According to another feature of the present disclosure, the first planarization layer may extend to overlap at least a part of the non-display area, and each of the cathode and the protective layer may extend to overlap at least a part of the non-display area and be disposed to cover a side surface of the first planarization layer exposed by the trench structure.

According to another feature of the present disclosure, the ends of the cathode and the ends of the protective layer may be located within the trench structure.

According to another feature of the present disclosure, the end of the organic layer may be located further inward than the end of the first planarization layer, and each of the cathode and the protective layer may be disposed to cover the side surface of the organic layer.

According to another feature of the present disclosure, the adhesive layer may be disposed to fill the inside of the trench structure.

According to another feature of the present disclosure, the adhesive layer may include a getter, and the second substrate may be a metal substrate.

According to another feature of the present disclosure, the plurality of protrusions may have a matrix structure including a bar shape extending in a first direction of the display device and a bar shape extending in a second direction different from the first direction.

According to another feature of the present disclosure, the plurality of protrusions may each independently have a circle shape, an elliptical shape, or a polygonal shape, and each of the plurality of protrusions may be arranged in an island shape.

According to another feature of the present disclosure, the protective layer may be further disposed on the plurality of protrusions.

Each of the plurality of protrusions may be in the form of a bar extending in the first direction of the display device, and the protective layer disposed on the plurality of protrusions may be in the form of a bar extending in the first direction, which is the same as the plurality of protrusions, or in the form of a bar extending in the second direction different from the first direction.

According to another feature of the present disclosure, the protective layer may be further disposed between the plurality of protrusions.

According to another feature of the present disclosure, the protective layer may be further disposed on each of the plurality of protrusions and between the plurality of protrusions.

According to another feature of the present disclosure, the protective layer further disposed between the plurality of protrusions may have a thickness equal to or thinner than the thickness of the protrusion.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a first substrate including a display area and a non-display area;
a planarization layer disposed on the first substrate in the display area and the non-display area;
an anode disposed on the planarization layer;
an organic layer disposed on the anode;
a cathode disposed on the organic layer;
a protective layer disposed on the cathode;
a second substrate disposed on the protective layer so as to face the first substrate; and
an adhesive layer disposed on the protective layer and the second substrate and bonding the first substrate and the second substrate,
wherein a trench structure is disposed in the non-display area, the trench structure being formed by removing a part of the planarization layer,
wherein the planarization layer includes a first planarization layer disposed in the display area and a second planarization layer disposed in the non-display area,
wherein the trench structure is disposed between the first planarization layer and the second planarization layer, and
wherein the second planarization layer includes a plurality of protrusions on the upper surface of the second planarization layer.

2. The display device according to claim 1, wherein the protective layer is disposed to cover a side surface of the first planarization layer exposed by the trench structure.

3. The display device according to claim 1, wherein an upper surface of the second planarization layer is disposed to be in direct contact with the adhesive layer.

4. The display device according to claim 1, wherein the first planarization layer extends to overlap at least a portion of the non-display area, and
wherein each of the cathode and the protective layer extends to overlap at least a portion of the non-display area and is disposed to cover a side surface of the first planarization layer exposed by the trench structure.

5. The display device according to claim 4, wherein ends of the cathode and ends of the protective layer are located in the trench structure.

6. The display device according to claim 4, wherein an end of the organic layer is located further inward than an end of the first planarization layer, and
wherein each of the cathode and the protective layer is disposed to cover a side surface of the organic layer.

7. The display device according to claim 1, wherein the adhesive layer is disposed to extend into the trench structure.

8. The display device according to claim 1, wherein the adhesive layer includes a getter and the second substrate is a metal substrate.

9. The display device according to claim 1, wherein the plurality of protrusions has a matrix structure including a bar shape extending in a first direction of the display device and a bar shape extending in a second direction different from the first direction.

10. The display device according to claim 1, wherein the plurality of protrusions is each independently circle, elliptical, or polygonal, and each of the plurality of protrusions is arranged in an island shape.

11. The display device according to claim 1, wherein the protective layer is further disposed on the plurality of protrusions.

12. The display device according to claim 11, wherein each of the plurality of protrusions is in the form of a bar extending in the first direction of the display device, and
wherein the protective layer disposed on the plurality of protrusions is in the form of a bar extending in the first direction, which is the same as the plurality of protrusions, or in the form of a bar extending in the second direction different from the first direction.

13. The display device according to claim 1, wherein the protective layer is further disposed between the plurality of protrusions.

14. The display device according to claim 1, wherein the protective layer is further disposed on each of the plurality of protrusions and between the plurality of protrusions.

15. The display device according to claim 13, wherein the protective layer further disposed between the plurality of protrusions has a thickness equal to or thinner than the thickness of the protrusions.

16. The display device according to claim 14, wherein the protective layer further disposed between the plurality of protrusions has a thickness equal to or thinner than the thickness of the protrusions.
